(19) United States
(12) Patent Application Publication
(10) Pub. No.: US 2010/0008054 A1
(43) Pub. Date: Jan. 14, 2010

(54) Solder interface between integrated connector terminals and printed circuit board

(76) Inventor: Patrick L. Dotson, Kokomo, IN (US)

Correspondence Address: Delphi Technologies, Inc., M/C 480-410-202, PO BOX 5052, Troy, MI, 48007, US

(21) Appl. No.: 12/217,807

(22) Filed: Jul. 9, 2008

(51) Int. Cl. H05K 5/00; H01R 9/00

(52) U.S. Cl. 361/752; 29/843

(57) ABSTRACT

A process for electrically and mechanically attaching a connector to a printed circuit board contained in a housing involves steps of providing a housing member having an electrical connector integrally extending through a wall of the housing member; providing a circuit board having an electrical contact pad and a solder bump on the electrical contact pad; positioning the printed circuit board on the housing member with the solder bump contacting the terminal to form a pre-assembly; liquefying the solder bump; and re-solidifying the solder bump to establish attachment of the connector to the printed circuit board. Liquefying the solder bump and re-solidifying the solder bump can be achieved using either a conventional reflow technique in which the entire sub-assembly is heated, or a hot bar apparatus may be employed to selectively heat thermally conductive pads that are in thermal contact with solder bumps on the printed circuit board.

### TECHNICAL FIELD

This invention relates to electrical connectors integrated into a product housing and more particularly to a process for electrically and mechanically attaching connectors to a printed circuit board contained in a housing.

### BACKGROUND OF THE INVENTION

Solderless compliant pin technology is commonplace in electronic assemblies. Electrical connector terminals are insert-molded into a product housing, creating a housing with an integral connector. This eliminates the need for a separate loose connector attached to a circuit board. It also eliminates sealing issues in products that require a sealed assembly. Electrical connections between a circuit board and an integral electrical connector may be achieved by an interference fit between the connector terminals and through-holes in the circuit board. This process eliminates the need for expensive secondary stick-lead soldering or wave-soldering processes during the final assembly of an electronic product.

While compliant pin technology represents an improvement compared to older technologies, it requires expensive secondary manufacturing equipment, such as a press used to install the circuit board into the housing. Verification of the integrity of the circuit board/connector terminal interface is also problematic. Expensive vision-based verification equipment may be required for high-volume applications.

### SUMMARY OF THE INVENTION

The invention provides many of the benefits of compliant pin technology, while eliminating the need for additional manufacturing equipment and processes.

In accordance with the invention, electrical connectors are integral with and extend through a housing member. The connectors include terminals located at an interior side of the housing. The terminals are designed for surface-mount solder connection with a circuit board. The printed circuit board is positioned on the housing member prior to a surface-mount soldering step. The resulting pre-assembly is then subjected to a soldering step. In a single step, the surface-mount assembly of the electrical components and the electrical connection between the circuit board and the integral housing connector is completed.

The soldering step may involve a conventional reflow technique in which the entire assembly is heated to liquefy solder bumps.

Soldering of the surface-mount electrical components may also be completed prior to installation of the circuit board in the housing, with the electrical connection between the circuit board and the housing being completed in a second reflow solder process.

Alternatively, a hot bar apparatus may be employed to selectively heat thermally conductive pads that are in thermal contact with solder bumps on the printed circuit board. The assembly process of the invention has several potential advantages. First, in certain embodiments secondary manufacturing equipment for installing a printed circuit board into a product housing may be eliminated. Second, in certain embodiments the printed circuit board assembly and the printed circuit board/housing assembly can be completed in a single step. Finally, in most embodiments the printed circuit board/product connector interface can be verified using existing in-line testing procedures, eliminating the need for more expensive verification equipment.

These and other features, advantages and objects of the present invention will be further understood and appreciated by those skilled in the art by reference to the following specification, claims and appended drawings.

### BRIEF DESCRIPTION OF THE DRAWINGS

The present invention will now be described, by way of example, with reference to the accompanying drawings, in which:

FIG. 1 is a perspective view of a housing having insert-molded connectors and which is adapted for receiving a printed circuit board.

FIG. 2 is a perspective view of a hot bar being applied to the circuit board to effect a reflow solder connection between the circuit board and the insert-molded connectors.

FIG. 3 is an enlarged perspective view showing details of the reflowed solder interface on the printed circuit board.

FIG. 4 is a cross-sectional view along lines IV-IV of FIG. 3.

### DESCRIPTION OF THE PREFERRED EMBODIMENTS

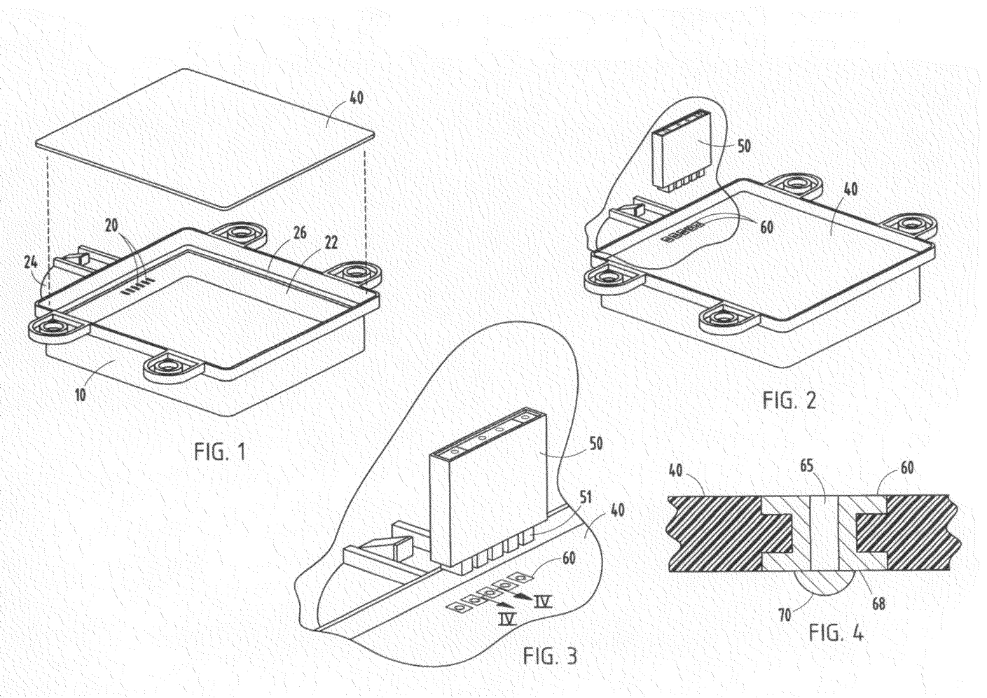

Shown in FIG. 1 is a housing member 10 having insert-molded connectors 20 that extend through wall 22 of housing member 10 and into connector 24. Housing member 10 includes a printed circuit board receiving ledge 26 that extends around an inner perimeter of the housing. Housing member 10 may be comprised of generally any moldable material, such as a thermoplastic polymeric material.

As shown in FIG. 2, after printed circuit board 40 is positioned on ledge 26 it is ready to be attached to connectors 20 by application of a hot bar 50 to solder pads 60. The terminals of metal contacts 20 are located at an interior side of housing member 10 and are designed for surface-mount solder connection with circuit board 40.

As shown in FIG. 3, hot bar 50 is configured with a plurality of fingers 51 that selectively and precisely apply heat to corresponding heat conductive solder pads 60 on a side of printed circuit board 40 that is opposite the side on which the connector terminals are located. Heat is conducted through the pads and liquefies solder at the connector terminals. When hot bar 50 is removed, the solder cools and solidifies to complete the electrical connection.

As shown in greater detail in FIG. 4, each of the thermally conductive pads 60 conducts heat to a corresponding thermally conductive thru-hole 65 that provides a thermally conductive path between pads 60, electrical contact pads 68 and solder bumps 70, which are located on a side of circuit board 40 opposite pad 60. Application of heat from fingers 51 of hot bar 50 causes the solder bumps to liquefy and removal of the hot bar causes cooling and re-solidification of the solder, and the formation of a connection between circuit board 40 and each of the individual connectors 20.

As an alternative, a standard reflow soldering technique may be employed. This involves heating the entire pre-assembly, usually in an oven, until the solder on the printed circuit board liquefies. Thereafter, the assembly is cooled causing the solder to solidify, providing an electrical connection. In such case, hot bar 50 is not used, and pad 60 and thermally conductive thru-hole 65 are not required.

It is conceivable that reflow soldering of surface-mount devices could be achieved concurrently with reflow solder connection of connectors 20 to printed circuit board 40. Alternatively, surface-mount devices may be connected to the circuit board in a separate operation.

The process of the invention represents an advance in surface-mount solder technology that provides advantages compared to existing processes by achieving a low-cost, yet robust method for fabricating a printed circuit board/housing assembly that contains a connector that is integrated into the housing.

It will be understood by those who practice the invention and those skilled in the art, that various modifications and improvements may be made to the invention without departing from the spirit of the disclosed concept. The scope of protection afforded is to be determined by the claims and by the breadth of interpretation allowed by law.

1. A process for electrically and mechanically attaching a connector to a printed circuit board contained in a housing, comprising:
providing a housing member having an electrical connector integrally extending through a wall of the housing member, the connector having a terminal at an interior side of the housing member;
providing a circuit board having an electrical contact pad and a solder bump on the electrical contact pad;
positioning the printed circuit board on the housing member with the solder bump contacting the terminal to form a pre-assembly;
heating and liquefying the solder bump; and
cooling and re-solidifying the solder bump to establish an electrical and physical attachment of the connector to the printed circuit board.

2. The process of claim 1, wherein the step of applying heat to the thermally conductive pad is achieved by selectively and precisely applying heat to a corresponding thermally conductive pad on the printed circuit board, the thermally conductive pad being thermally connected to the electrical contact pad on the opposite side of the circuit board.

3. The process of claim 1, wherein the housing member includes a printed circuit board receiving ledge that extends around an inner perimeter of the housing member.

4. The process of claim 1, wherein the connector terminal that extends through a wall of the housing member is insert-molded into the wall of the housing member.

5. The process of claim 4, wherein the housing member is comprised of a thermoplastic material.

6. The process of claim 1, wherein the step of applying heat to the thermally conductive pad includes heating the pre-assembly in an oven.

7. An electronic device comprising:
a housing having an integral connector extending through a wall of the housing member, the connector having a terminal at an interior side of the housing member; and
a circuit board having an electrical contact pad, the terminal surface-mount solder connected to the electrical contact pad.

8. The device of claim 7, wherein the housing member includes a printed circuit board receiving ledge that extends around an inner perimeter of the housing member, and edges of the circuit board are seated on the printed circuit board receiving ledge.

9. The device of claim 7, wherein the connector terminal that extends through a wall of the housing member is insert-molded into the wall of the housing member.

10. The device of claim 9, wherein the housing member is comprised of a thermoplastic material.
